(19) United States
(12) Patent Application Publication
(10) Pub. No.: US 2024/0143281 A1
(43) Pub. Date: May 2, 2024

(54) SEMICONDUCTOR DEVICE

(71) Applicant: RENESAS ELECTRONICS CORPORATION, Tokyo (JP)

(72) Inventors: Shinji TANAKA, Tokyo (JP); Daiki KITAGATA, Tokyo (JP)

(21) Appl. No.: 18/471,683

(22) Filed: Sep. 21, 2023

(30) Foreign Application Priority Data
Oct. 31, 2022 (JP) 2022-174932

(51) Int. Cl. G06F 7/544

(52) U.S. Cl. CPC G06F 7/5443

(57) ABSTRACT

A related-art semiconductor device has a problem that is a large operation error. A semiconductor device according to an embodiment includes: an input control circuit dividing a plurality of bit values representing an input value into a plurality of division values each having a predetermined number of bits, and outputting the division values; a plurality of memory units each including a plurality of memory cells each outputting a product of a held value represented by a ternary value and any one of the plurality of bit values representing the input value, each of the plurality of memory units corresponding to any one of the division values; and a sum operation circuit performing sum operation processing to an output value to be output for each of the division values, and outputting a final operation result value.

### CROSS-REFERENCE TO RELATED APPLICATION

The disclosure of Japanese Patent Application No. 2022-174932 filed on Oct. 31, 2022, including the specification, drawings and abstract is incorporated herein by reference in its entirety.

### BACKGROUND

The present invention relates to a semiconductor device, and relates to, for example, a semiconductor device including a memory having a product-sum operation function.

There is disclosed technique listed below.
[Patent Document 1] Japanese Unexamined Patent Application Publication No. 2020-129582

In recent years, artificial intelligence has been used in many fields. In the artificial intelligence, a large amount of a product-sum operation needs to be performed. Product-sum operation processing is accelerated by a GPU (Graphics Processing Unit) or others. Not only the product-sum operation processing but also a large amount of data transfer processing accompanied by the processing occur. There is a problem that is extremely large power consumption for performing the processing. The Patent Document 1 discloses a technique related to a semiconductor device that processes a large amount of a product-sum operation with low power consumption.

The Patent Document 1 discloses a product-sum operation memory cell connected to two data lines, storing ternary data, and performing a product-sum operation among the stored data, input data having been input, and respective data on the data lines.

### SUMMARY

However, the semiconductor device described in the Patent Document 1 has a problem that an error increases when a current for driving the data lines by the memory cell increases.

Other problems and novel characteristics will be apparent from the description of the present specification and the accompanying drawings.

A semiconductor device according to an embodiment includes: an input control circuit dividing a plurality of bit values representing an input value into division values each having a predetermined number of bits and outputs the division values; a plurality of memory units each including a plurality of memory cells each outputting a product of a held value represented by a ternary value and any one of the plurality of bit values representing the input value and each corresponding to any one of the plurality of division values; and a sum operation circuit performing a sum operation processing to an output value to be output for each of the division values and outputting a final operation result value.

By the semiconductor device according to the embodiment, a driving current for driving a data line can be suppressed to a predetermined value or less to increase an operation accuracy.

### BRIEF DESCRIPTIONS OF THE DRAWINGS

FIG. 1 is a block diagram of a semiconductor device according to a first embodiment.

FIG. 2 is a detailed block diagram of the semiconductor device according to the first embodiment.

FIG. 3 is a circuit diagram of an information processing reference cell according to the first embodiment.

FIG. 4 is a circuit diagram of a memory cell according to the first embodiment.

FIG. 5 is a circuit diagram of a determination circuit according to the first embodiment.

FIG. 6 is a flowchart for explaining operation of the determination circuit according to the first embodiment.

FIG. 7 is a timing chart for explaining operation of the semiconductor device according to the first embodiment.

FIG. 8 is a detailed block diagram of a semiconductor device according to a second embodiment.

FIG. 9 is a timing chart for explaining operation of the semiconductor device according to the second embodiment.

FIG. 10 is a detailed block diagram of a semiconductor device according to a third embodiment.

FIG. 11 is a timing chart for explaining first operation of the semiconductor device according to the third embodiment.

FIG. 12 is a timing chart for explaining second operation of the semiconductor device according to the third embodiment.

FIG. 13 is a block diagram of a semiconductor device according to a fourth embodiment.

FIG. 14 is a detailed block diagram of a collective operation processing memory arranged in a second memory region of the semiconductor device according to the fourth embodiment.

### DETAILED DESCRIPTION

For clarity of explanation, the following description and drawings are appropriately omitted and simplified. In the drawings, the same components are respectively denoted by the same reference numerals, and description thereof is not repeated as needed.

A semiconductor device described below has a configuration in which a plurality of memory cells capable of holding a ternary value are connected to a data line shard among the plurality of memory cells. The product-sum operation is performed by adding respective products of input values to the memory cells and values stored in the memory cells are added on the data line. A product-sum operation result is finally output as a multi-bit output value after being sequentially compared with a reference value to be output by an information processing reference cell. Hereinafter, such a semiconductor device will be described in detail.

### First Embodiment

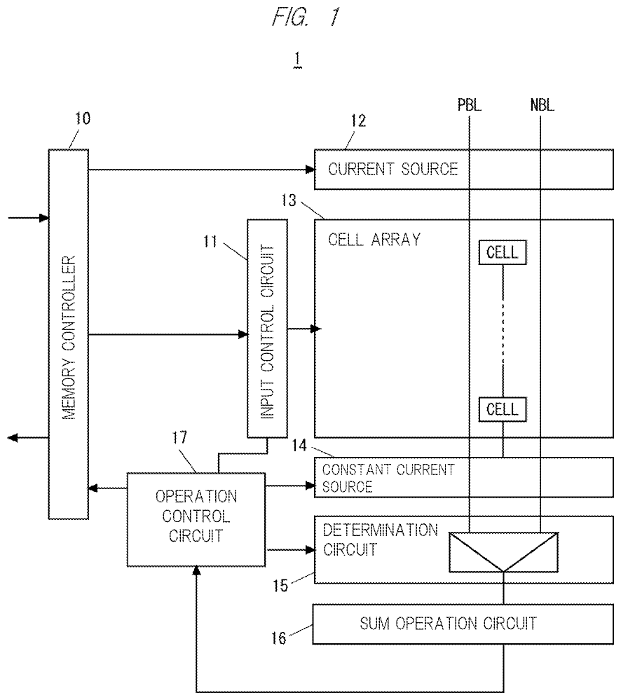

First, FIG. 1 is a block diagram of a semiconductor device according to a first embodiment. As illustrated in FIG. 1, a semiconductor device 1 according to the first embodiment includes a memory controller 10, an input control circuit 11, a current source 12, a cell array 13, a constant current source 14, a determination circuit 15, a sum operation circuit 16, and an operation control circuit 17.

The memory controller 10 is an external interface for the semiconductor device 1, and receives an input value from a semiconductor device provided outside and outputs an operation result value generated in the semiconductor device 1 to an external device. The memory controller 10 may have a function of controlling a power supply such as the current source 12 in the semiconductor device 1.

The input control circuit 11 converts an input value having been input via the memory controller 10 into a signal for controlling memory cells provided in the cell array 13, and drives the memory cells. More specifically, in the first embodiment, the input control circuit 11 has a function of dividing a plurality of bit values representing an input value into division values each having a predetermined number of bits, and outputting the division values. In the first embodiment, the semiconductor device 1 collectively gives the plurality of division values to a plurality of memory units described below.

The current source 12 generates a current to be fed to a first data line (hereinafter referred to as a data line PBL) and a second data line (hereinafter referred to as a data line NBL) in the cell array 13. In the cell array 13, the memory cells are arranged in a grid shape. Although described in detail later, the semiconductor device 1 according to the first embodiment collectively controls, as the memory unit, the memory cells, the number of which corresponds to the number of divisions in a case where the input value is divided into the division values.

The constant current source 14 generates a constant current for driving the memory cells in the cell array 13. The determination circuit 15 determines whether respective product-sum operation results are large or small from the memory cells in the cell array 13, and sequentially outputs bits composing a final output value one by one. The sum operation circuit 16 operates the sum of output values respectively determined for the division values by the determination circuit, to calculate a final operation result value.

The operation control circuit 17 generates the final output value composed of multiple bits from the operation result value output by the sum operation circuit 16, and transmits the output value to the memory controller 10. The operation control circuit 17 also functions as a control circuit that controls an AD conversion REF cell and a determination circuit described later. More specifically, in the semiconductor device 1, the operation control circuit 17 controls an information processing reference cell and a determination circuit such that the determination circuit performs operation processing within one period in parallel.

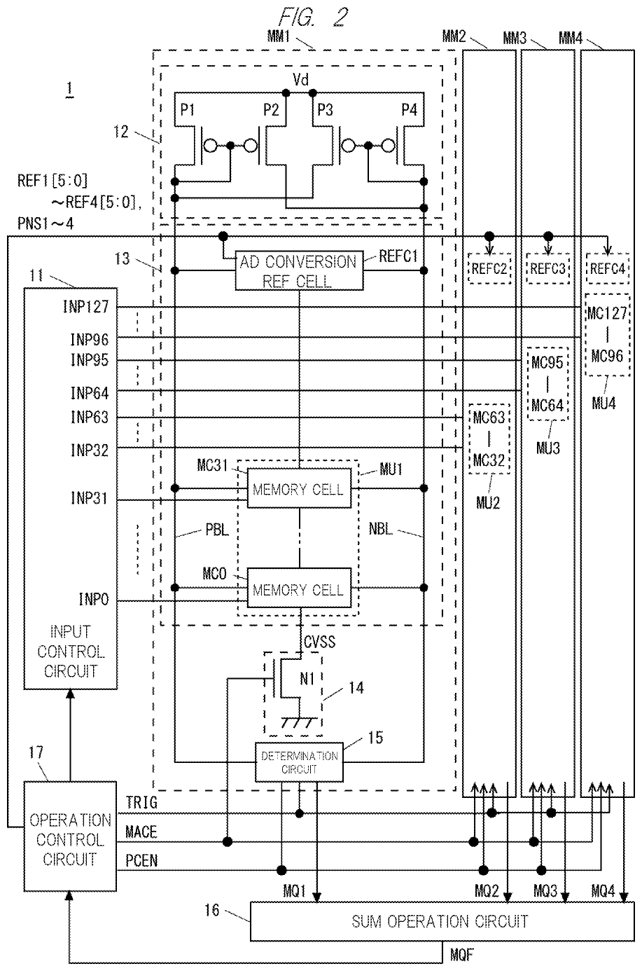

Hereinafter, description will be made while paying attention to respective configurations of the input control circuit 11, the current source 12, the cell array 13, the constant current source 14, the determination circuit 15, the sum operation circuit 16, and the operation control circuit 17. FIG. 2 shows a detailed block diagram of the semiconductor device according to the first embodiment.

In an example illustrated in FIG. 2, the input control circuit 11 divides an input value into four division values. Then, four memory units MU1 to MU4 are respectively provided for the four division values. That is, each of the memory units MU1 to MU4 corresponds to any one of the four division values. Each of the memory units MU1 to MU4 includes memory cells each outputting a product of a held value represented by a ternary value and any one of a plurality of bit values representing the input value. In the example illustrated in FIG. 2, each of the division values is a 32-bit value, and each of the memory units MU1 to MU4 includes 32 memory cells. Specifically, the memory unit MU1 includes memory cells MC0 to MC31, the memory unit MU2 includes memory cells MC32 to MC63, the memory unit MU3 includes memory cells MC64 to MC95, and the memory unit MU4 includes memory cells MC96 to MC127.

In the semiconductor device 1 illustrated in FIG. 2, the current source 12, the constant current source 14, the determination circuit 15, the data line PBL, and the data line NBL are provided for each of the memory units. In FIG. 2, a set of the current source 12, the constant current source 14, the determination circuit 15, the first data line PBL, and the second data line NBL is illustrated as a memory module for each of the memory units. Specifically, a memory module MM1 is a memory module corresponding to the memory unit MU1, a memory module MM2 is a memory module corresponding to the memory unit MU2, a memory module MM3 is a memory module corresponding to the memory unit MU3, and a memory module MM4 is a memory module corresponding to the memory unit MU4. The memory modules MM1 to MM4 only differ from one another in the division values respectively corresponding to the memory units included therein, and respectively have the same configurations with one another. Accordingly, the configurations of the memory modules will be described below while taking the memory module MM1 as an example.

As illustrated in FIG. 2, in the memory module MM1 according to the first embodiment, the plurality of memory cells (e.g., MC0 to MC31) included in the memory unit MU1 are provided to be connected to the data lines PBL and NBL. Although the division value to be given to the memory cells is composed of multiple bits, corresponding one of the bits of the division value is input to each of the memory cells. The memory cell outputs a product of a 1-bit input value and a held value represented by a ternary value. The memory cells include a first memory cell that electrically connects the data line PBL to the constant current source 14 when a first value is held therein and a second memory cell that electrically connects the data line NBL to the constant current source 14 when a second value is held therein although described in detail later. That is, the memory cell that outputs the first value among the plurality of memory cells is electrically connected to the data line PBL. The memory cell that outputs the second value among the plurality of memory cells is electrically connected to the data line NBL.

An information processing reference cell (e.g., an AD conversion REF cell REFC1) is provided to be connected to the data lines PBL and NBL. The AD conversion REF cell is included in each of the memory modules MM1 to MM4. FIG. 2 illustrates AD conversion REF cells REFC1 to REFC4, respectively, as the AD conversion REF cells corresponding to the memory modules MM1 to MM4. Each of the AD conversion REF cells REFC1 to REFC4 gives a reference value that changes for each information processing cycle to either one of the data line PBL and the data line NBL. The AD conversion REF cells REFC1 to REFC4 respectively change the reference values in response to reference control signals REF1 to REF4. The reference control signals REF1 to REF4 are output by the operation control circuit 17.

The current source 12 includes PMOS transistors P1 to P4. The PMOS transistor P1 has its source connected to a power supply wiring Vd, has its drain connected to the data line PBL, and has its gate connected to the drain in common. The PMOS transistor P2 has its gate connected to the gate of the PMOS transistor P1 in common, has its source connected to the power supply wiring Vd, and has its drain connected to the data line NBL. The PMOS transistor P3 has its gate connected to a gate of the PMOS transistor P4 in common, has its source connected to the power supply wiring Vd, and has its drain connected to the data line PBL. The PMOS transistor P4 has its source connected to the power supply wiring Vd, has its gate connected to its gate in common, and has its drain connected to the data line NBL.

That is, the semiconductor device 1 makes flow of a current that is a sum of a current generated by the diode-connected PMOS transistor that supplies a current to one of the data lines PBL and NBL and a current generated by the diode-connected PMOS transistor that supplies a current to the other data line. As a result, in the semiconductor device 1, the current source 12 is used to reduce a variation between the currents to be respectively supplied to the data lines PBL and NBL.

The constant current source 14 includes an NMOS transistors N1. The NMOS transistor N1 has its source grounded, has its gate receiving a product-sum operation mode enable signal MACE, and has its drain connected to a cell ground wiring CVSS. The cell ground wiring CVSS is connected to the plurality of memory cells and the AD conversion REF cell REFC1. The constant current source 14 generates a driving current for causing the plurality of memory cells and the AD conversion REF cell REFC1 to drive the data line PBL and the data line NBL via the cell ground wiring CVSS. The sum-product operation mode enable signal MACE to be fed to the constant current source 14 is output by the operation control circuit 17.

For each information processing cycle, the determination circuit 15 outputs a binary signal representing a value that differs depending on which one of the number of memory cells connected to the data line PBL and the number of memory cells connected to the data line NBL is larger or smaller than the other. A trigger signal TRIG and a precharge signal PCEN are input as control signals to the determination circuit 15. The determination circuit 15 operates in a period during which the trigger signal TRIG is in an enable state (e.g., at a high level).

Then, an example of specific circuits of circuit blocks illustrated in FIG. 2 will be described. Each of the circuit blocks can be also achieved by even a component other than the following circuits.

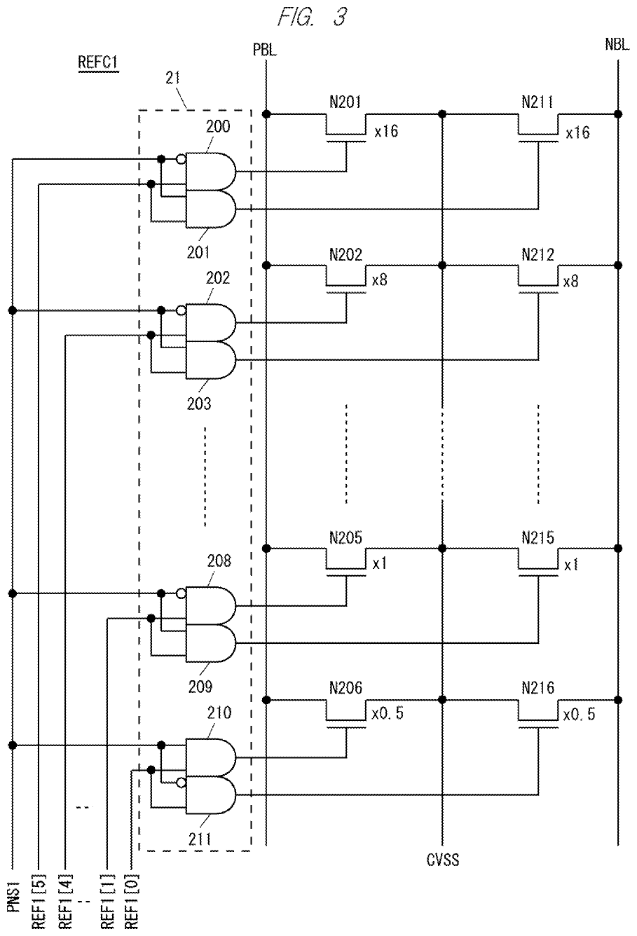

The AD conversion REF cells REFC1 to REFC4 respectively have the same configurations. In the following description, the configurations of the AD conversion REF cells will be described while taking the AD conversion REF cell REFC1 as an example. FIG. 3 is a circuit diagram illustrating the AD conversion REF cell REFC1 according to the first embodiment. As illustrated in FIG. 3, the AD conversion REF cell REFC1 has a plurality of sets of two transistors connected in series between the data line PBL and the data line NBL. The AD conversion REF cell REFC1 includes a control logic 21 that controls the transistors connected between the data line PBL and the data line NBL.

The sets of two transistors connected in series between the data line PBL and the data line NBL differ in transistor size. FIG. 3 illustrates an example in which the AD conversion REF cell REFC1 is designed such that the transistor size is 16, 8, 4, 2, 1, and 0.5. The cell ground wiring CVSS is connected to a node at which the transistors constituting each transistor set are connected. The control logic 21 has an AND gate with inverting input and an AND gate for each of the transistor sets. A polarity control signal PNS1 is input to an inverting input terminal of the AND gate with inverting input and one terminal of the AND gate. A reference control signal composed of bits corresponding to the corresponding transistor set among the reference control signals REF1 is input to a forward input terminal of the AND gate with inverting input and the other terminal of the AND gate. For example, in the example illustrated in FIG. 3, the highest-order bit of the reference control signal REF1 is input to the control logic 21 corresponding to the set of transistors, the transistor size of which is 16. And, the smaller the transistor size is, the lower the order of the bit in the reference control signal REF1 to be input is. In the AD conversion REF cell REFC1, the transistor on the data line PBL side is controlled by an output of the AND gate with inverting input, and the transistor on the data line NBL side is controlled by an output of the AND gate. For the control logic 21 corresponding to the set of transistors, the transistor size of which is 0.5, the transistor on the data line NBL side is controlled by an output of the AND gate with inverting input, and the transistor on the data line PBL side is controlled by an output of the AND gate.

As a result, in the AD conversion REF cell REFC1, when the polarity control signal PNS1 selects the data line PBL side (e.g., is at a low level), a current is drawn in the data line PBL from the data line PBL to the cell ground wiring CVSS by the transistor to be specified by the reference control signal REF1. On the other hand, when the polarity control signal PNS1 selects the data line NBL side (e.g., is at a high level), a current is drawn in the data line NBL from the data line NBL to the cell ground wiring CVSS by the transistor to be specified by the reference control signal REF1. For the transistors (e.g., N206 and N216), the transistor size of which is set to 0.5, a current is drawn from the opposite data line to the data line of the other transistor to the cell ground wiring CVSS.

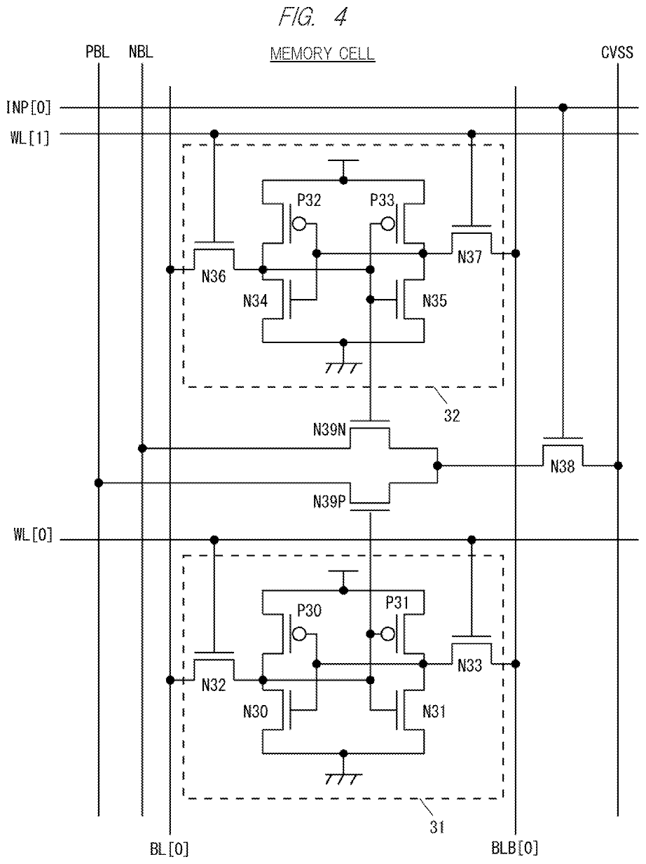

FIG. 4 is a circuit diagram of the memory cell according to the first embodiment. FIG. 4 illustrates only the memory cell MC0 as a representative of the plurality of memory cells illustrated in FIG. 2. As illustrated in FIG. 4, the memory cell includes a first memory cell 31 and a second memory cell 32. The memory cell includes NMOS transistors N38, N39P, and N39N. The NMOS transistor N38 has its one end connected to the cell ground wiring CVSS and has its other end connected to respective one ends of the NMOS transistor N39P and the NMOS transistor N39N. The NMOS transistor N38 has its gate receiving a 0-th bit of an input value INP. The data line PBL is connected to the other end of the NMOS transistor N39P. The NMOS transistor N39P has its gate connected to the first memory cell 31. The data line NBL is connected to the other end of the NMOS transistor N39N. The NMOS transistor N39N has its gate connected to the second memory cell 32.

The first memory cell 31 and the second memory cell 32 respectively have configurations each functioning as an SRAM (Static Random Memory). Specifically, the first memory cell 31 includes PMOS transistors P30 and P31 and NMOS transistors N30 to N33. The PMOS transistor P30 and the NMOS transistor N30 are connected in series between a power supply wiring and a ground wiring, and have their respective gates connected in common. The PMOS transistor P31 and the NMOS transistor N31 are connected in series between the power supply wiring and the ground wiring, and have their respective gates connected in common. The respective gates of the PMOS transistor P30 and the NMOS transistor N30 are connected to a node at which the PMOS transistor P31 and the NMOS transistor N31 are connected and one end of the NMOS transistor N33. The respective gates of the PMOS transistor P31 and the NMOS transistor N31 are connected to a node at which the PMOS transistor P30 and the NMOS transistor N30 are connected and one end of the NMOS transistor N32. The other end of the NMOS transistor N32 is connected to a complementary bit line BL. The other end of the NMOS transistor N33 is connected to a complementary bit line BLB. The NMOS transistors N32 and N33 have their respective gates connected to a word line WL[0].

The second memory cell 32 includes PMOS transistors P32 and P33 and NMOS transistors N34 to N37. The PMOS transistor P32 and the NMOS transistor N34 are connected in series between a power supply wiring and a ground wiring, and have their respective gates connected in common. The PMOS transistor P33 and the NMOS transistor N35 are connected in series between the power supply wiring and the ground wiring, and have their respective gates connected in common. The respective gates of the PMOS transistor P32 and the NMOS transistor N34 are connected to a node at which the PMOS transistor P33 and the NMOS transistor N35 are connected and one end of the NMOS transistor N37. The respective gates of the PMOS transistor P33 and the NMOS transistor N35 are connected to a node at which the PMOS transistor P32 and the NMOS transistor N34 are connected and one end of the NMOS transistor N36. The other end of the NMOS transistor N36 is connected to the complementary bit line BL. The other end of the NMOS transistor N37 is connected to the complementary bit line BLB. The NMOS transistors N36 and N37 have their respective gates connected to a word line WL[1].

A value is written into the memory cell by using the complementary bit lines BL and BLB to determine a state of an inverter in the first memory cell 31 in a state with the word line WL[0] brought into a high level. Also, a value is written into the memory cell by using the complementary bit lines BL and BLB to determine a state of an inverter in the second memory cell 32 in a state with the word line WL[1] brought into a high level.

The memory cell controls an opened/closed state of the NMOS transistor N39P by using a value to be held in the inverter constituted by the PMOS transistor P30 and the NMOS transistor N30. The memory cell controls an opened/closed state of the NMOS transistor N39N by using a value to be held in the inverter constituted by the PMOS transistor P32 and the NMOS transistor N34.

It is assumed that the memory cell illustrated in FIG. 4 stores a logical value “0” when both the first memory cell 31 and the second memory cell 32 store a logical value “0”. It is assumed that the memory cell stores a logical value “+1” when the first memory cell 31 stores a logical value “1” and the second memory cell 32 stores a logical value “0”. Further, it is assumed that the memory cell stores a logical value “−1” when the first memory cell 31 stores a logical value “0” and the second memory cell 32 stores a logical value “1”.

As a result, when the memory cell stores a logical value “0”, both the NMOS transistor N39P and the NMOS transistor N39N are turned off. Even if the input value INP is a logical value “1”, no current flows from the data lines PBL and NBL to the constant current source 14.

On the other hand, when the memory cell stores a logical value “+1”, the NMOS transistor N39P is turned on, and the NMOS transistor N39N is turned off. At this time, if the input value INP is a logical value “1”, a current flows from the data line PBL to the constant current source 14 via the NMOS transistor N39P and the NMOS transistor N38 that remain turned on, and a voltage of the data line PBL decreases. At this time, a voltage of the data line NBL does not decrease. On the other hand, at this time, if the input value INP is a logical value “0”, the NMOS transistor N38 is turned off. Accordingly, no current flows from the data lines PBL and NBL to the constant current source 14, and the respective voltages of the data lines PBL and NBL do not decrease.

Further, when the memory cell stores a logical value “−1”, the NMOS transistor N39N is turned on, and the NMOS transistor N39P is turned off. At this time, if the input value INP is a logical value “1”, a current flows from the data line NBL to the constant current source 14 via the NMOS transistor N39N and the NMOS transistor N38 that remain turned on, and a voltage of the data line NBL decreases and a voltage of the data line PBL does not decrease. On the other hand, at this time, if the input value INP is a logical value “0”, the NMOS transistor N38 is turned off. Accordingly, no current flows from the data lines PBL and NBL to the constant current source 14, and the respective voltages of the data lines PBL and NBL do not decrease.

That is, in the memory cell, the first memory cell 31 can be considered to be used to store a logical value “+1” in the memory cell, and the second memory cell 32 can be considered to be used to store a logical value “−1” in the memory cell.

As a result, a product operation is executed between the ternary value stored in the memory cell and the input value INP. That is, six states that are “0×0”. “0×(+1)”, “0×(−1)”, “1×0”. “1×(+1)”, “1×(−1)” are formed in accordance with a logical value of the input value and a logical value of the memory cell. In this case, a product operation is executed between the logical value of the input value and the logical value stored in the memory cell. When a result of the product operation is a logical value “1”, a current flows between the data line PBL and the constant current source 14, and a voltage of the data line PBL decreases. On the other hand, when the result of the product operation is a logical value “−1”, a current flows between the data line NBL and the constant current source 14, and a voltage of the data line NBL decreases.

In the memory cell in the semiconductor device 1, currents respectively based on the product operation results of the plurality of memory cells connected to each of the data lines PBL and NBL are superimposed thereon, and a current and a voltage are determined on each of the data lines PBL and NBL. That is, for products respectively obtained in a plurality of memory cells, a sum operation is executed to find a sum by the data lines PBL and NBL. A product operation result as a result of the sum operation is output via the data lines PBL and NBL.

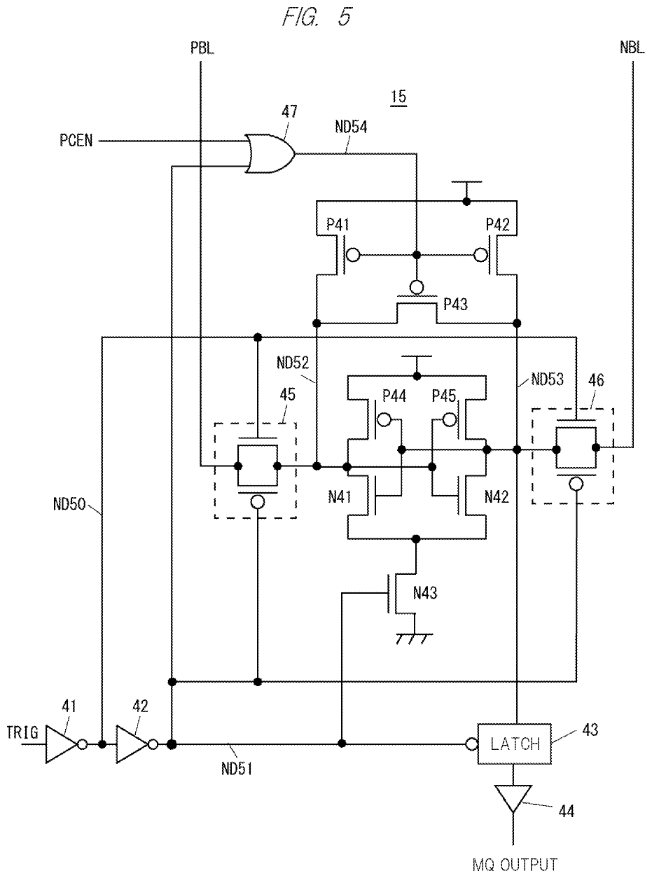

Then, details of the determination circuit 15 will be described. FIG. 5 is a circuit diagram of the determination circuit 15 according to the first embodiment. As illustrated in FIG. 5, the determination circuit 15 includes PMOS transistors P41 to P45, NMOS transistors N41 to N43, inverters 41 and 42, a latch 43, a buffer 44, transfer gates 45 and 46, and an OR gate 47.

The PMOS transistors P41 and P42 have their respective sources connected to a power supply wiring, and have their respective drains coupled to each other by the PMOS transistor P43. The drain of the PMOS transistor P41 is connected to a node ND52 at which the PMOS transistor P44 and the NMOS transistor N41 are connected. The drain of the PMOS transistor P42 is connected to a node ND53 at which the PMOS transistor P45 and the NMOS transistor N42 are connected. A precharge signal PCEN and a signal obtained by delaying a trigger signal TRIG by the inverters 41 and 42 are input to the OR gate 47, and a logical sum value of the two input signals is output to a node ND54. The PMOS transistors P41 to P43 have their respective gates receiving a signal of the node ND54. The PMOS transistors P41 to P43 are turned off if the signal of the node ND54 is at a high level, and are turned on if the signal of the node ND54 is at a low level.

The PMOS transistor P44 and the NMOS transistor N41 are connected in series between the power supply wiring and a drain of the NMOS transistor N43, and have their respective gates connected in common. The PMOS transistor P45 and the NMOS transistor N42 are connected in series between the power supply wiring and the drain of the NMOS transistor N43, and have their respective gates connected in common. The respective gates of the PMOS transistor P44 and the NMOS transistor N41 are connected to the node ND53 at which the PMOS transistor P45 and the NMOS transistor N42 are connected, and are connected to the data line NBL via the transfer gate 46. The respective gates of the PMOS transistor P45 and the NMOS transistor N42 are connected to the node ND52 at which the PMOS transistor P44 and the NMOS transistor N41 are connected, and are connected to the data line PBL via the transfer gate 45. That is, the PMOS transistors P44 and P45 and the NMOS transistors N41 to N43 have a latch-type sense amplifier structure using the NMOS transistor N43 as a current source.

The transfer gates 45 and 46 are turned on when the trigger signal TRIG is at a low level, and are turned off when the trigger signal TRIG is at a high level.

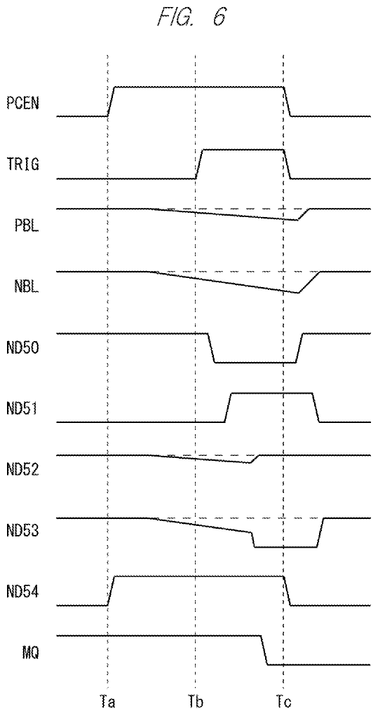

FIG. 6 is a timing chart for explaining operation of the determination circuit 15 according to the first embodiment. As illustrated in FIG. 6, in an initial state before a timing Ta in the determination circuit 15, a precharge signal PCEN and a trigger signal TRIG are brought into a low level, to precharge the node ND52 and the node ND53 to a high level. In the precharge, the transfer gates 45 and 46 are in a conductive state. Accordingly, the data lines PBL and NBL in addition to the nodes ND52 and ND53, are precharged to a high level. Then, at the timing Ta, the precharge is stopped by switching the precharge signal PCEN to a high level to switch the node ND54 to a high level. At this time, since the precharge is stopped, respective voltages of the data lines PBL and NBL are started to decrease by a current of the memory cell connected to the data lines PBL and NBL. Further, the transfer gates 45 and 46 also remain conductive. Accordingly, the levels of the nodes ND52 and ND53 become the same level as those of the data lines PBL and NBL, respectively, via the transfer gates 45 and 46. Then, at a timing Tb, the trigger signal TRIG is brought into a high level, to shut off the transfer gates. At the timing Tb, the NMOS transistor N43 is brought into the conductive state, and a determination cell constituted by the PMOS transistors P44 and P45 and the NMOS transistors N41 and N42 operates. The trigger signal TRIG is fed to the latch 43 via the inverters 41 and 42. The latch 43 is brought into an input passage state when the node ND51 is at a high level, and transmits a logical value of the node ND53 to the buffer 44. Then, at a timing Tc, the precharge signal PCEN and the trigger signal TRIG are switched from a high level to a low level so that the latch 43 holds a value input at that time. A latched output is output from the buffer 44 at the timing Tc or later.

That is, the determination circuit 15 loads respective values of the data lines PBL and NBL into the determination cell in a period during which the trigger signal TRIG is at a low level. In the determination circuit 15, the determination cell performs comparison as to which of respective potentials of the data line PBL and the data line NBL is larger in a state in which the trigger signal TRIG is at a high level. The determination circuit 15 feeds a drop edge of the trigger signal TRIG to the latch 43, to output, as an MQ output, a value determined by the determination cell to the sum operation circuit 16 by the buffer 44.

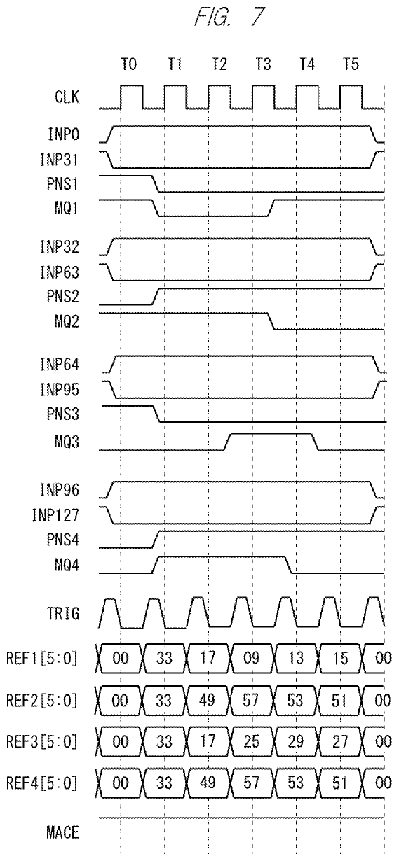

Then, operation of the semiconductor device 1 according to the first embodiment will be described. FIG. 7 is a timing chart for explaining the operation of the semiconductor device 1 according to the first embodiment. FIG. 7 illustrates only a value of the highest-order bit and a value of the lowest-order bit of each of division values as an input value, and clear illustration of a signal related to other bits is omitted. The semiconductor device 1 operates on the basis of an operation clock CLK. Accordingly, the operation clock CLK is illustrated in the timing chart. In the first embodiment, the constant current source 14 continues to operate during an operation period. Accordingly, a sum-product operation mode enable signal MACE is maintained at a high level.

As illustrated in FIG. 7, in the semiconductor device 1 according to the first embodiment, interference of the AD conversion REF cells REFC1 to REFC4 to the data lines PBL and NBL is stopped in response to the operation clock to be input at a first timing T0 of operation processing during an operation period, and the determination circuit 15 determines which of the data lines PBL and NBL is larger for each memory module. By comparison at the timing T0, the highest-order bit of an output value (e.g., an output value MQ1 to MQ4) corresponding to each of division values is determined. Respective logical values of polarity control signals PNS1 to PNS4 at a timing T1 or later are determined in accordance with the determination result of the timing T0.

Specifically, if the output value at a time point where the timing T0 ends is at a high level, the number of memory cells connected to the data line PBL is larger than the number of memory cells connected to the data line NBL. Accordingly, the polarity control signal at the timing T1 or later is brought into a high level so that a current is drawn from the data line NBL by each of the AD conversion REF cells REFC1 to REFC4.

On the other hand, if the output value at the time point where the timing T0 ends is at a low level, the number of memory cells connected to the data line NBL is larger than the number of memory cells connected to the data line PBL. Accordingly, the polarity control signal at the timing T1 or later is brought into a low level so that a current is drawn from the data line PBL by each of the AD conversion REF cells REFC1 to REFC4.

At the timing T1 or later, second to sixth bits of each of reference control signals REF1 to REF4 are sequentially turned on as a sequential analog/digital conversion sequence, to determine in accordance with the determination results (MQ1 to MQ4) whether the bits that have been turned on in the reference control signal REF1 to REF4 remain to be turned on or off. As a result of five cycles of sequential analog/digital conversion sequences, a current value of each of the AD conversion REF cells REFC1 to REFC4 corresponds to 32 if all the bits of the reference control signal are turned on, or corresponds to 0 if all the bits of the reference control signal are turned off. The respective current values of the AD conversion REF cells REFC1 to REFC4 at the timings T1 to T5 vary depending on the memory module.

Then, a sum of the respective output values MQ1 to MQ4 of the memory modules determined at the timing T5 is calculated by the sum operation circuit 16, and a value obtained by the calculation is output as an operation result value although not illustrated in FIG. 6.

From the foregoing description, the semiconductor device 1 according to the first embodiment divides an input value into division values, and is provided with memory units including a plurality of memory cells respectively corresponding to the division values. After the output value is determined for each memory unit, a sum of the determined output values is operated, and an operation result value is output. As a result, in the semiconductor device 1 according to the first embodiment, the number of memory cells to be connected to the data line is suppressed to a predetermined number or less. Accordingly, an operation error occurring because of the large number of memory cells to be connected to the data line can be suppressed. Specifically, in the first embodiment, a 128-bit input value is divided to generate four division values, and a maximum value of the number of memory cells to be connected to one data line pair is suppressed to 32 or less.

When a set of the memory cell and the bit line is not divided, eight information processing cycles are required to obtain an operation result value for a 128-bit input value. However, as illustrated in FIG. 6, in the semiconductor device 1 according to the first embodiment, a final operation result value can be obtained by six information processing cycles. That is, in the semiconductor device 1 according to the first embodiment, an increase in speed of the operation can be achieved.

### Second Embodiment

In a second embodiment, a semiconductor device 2 according to another embodiment of the semiconductor device 1 according to the first embodiment will be described. In the description of the second embodiment, the same components as the components described in the first embodiment are respectively denoted by the same reference numerals as those in the first embodiment, and description thereof is omitted.

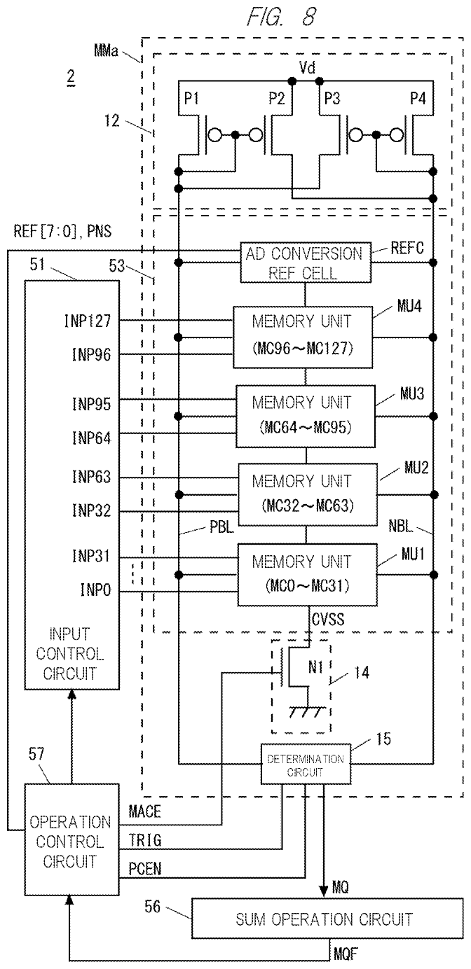

FIG. 8 is a block diagram of the semiconductor device 2 according to the second embodiment. Although a block illustrated in FIG. 8 is a block focused on a current source 12, a cell array 53, a constant current source 14, a determination circuit 15, an input control circuit 51, a sum operation circuit 56, and an operation control circuit 57 in the semiconductor device 2, the semiconductor device 2 includes other circuit blocks such as a memory controller 10 as similar to the semiconductor device 1 according to the first embodiment.

As illustrated in FIG. 8, the semiconductor device 2 according to the second embodiment includes the input control circuit 51, the cell array 53, the sum operation circuit 56, and the operation control circuit 57 instead of the input control circuit 11, the cell array 13, the sum operation circuit 16, and the operation control circuit 17 in the semiconductor device 1.

The input control circuit 51 gives the division values in time division to a plurality of memory units. Although the cell array 53 includes memory units MU1 to MU4 as similar to the cell array 13, all the memory units MU1 to MU4 are connected to one set of a data line PBL and a data line NBL. In the cell array 53, an AD conversion REF cell REFC, the current source 12, and the determination circuit 15 are each connected to the data lines PBL and NBL connecting the memory units MU1 to MU4. Further, in the cell array 53, the constant current source 14 is provided in common among the memory units MU1 to MU4. In FIG. 2, a memory module MMa includes the memory units MU1 to MU4, the AD conversion REF cell REFC, the current source 12, the constant current source 14, and the determination circuit 15.

In the semiconductor device 2, the memory units MU1 to MU4 are included in the memory module MMa, the respective numbers of AD conversion REF cells REFC and polarity control signals PNS included in the memory module MMa are each one. The semiconductor device 2 includes a plurality of memory modules, and each of the plurality of memory modules performs a sum-product operation of a held value and input values INP0 to INP127 to be output by the input control circuit 51. The sum operation circuit 56 is provided for each of the memory modules.

The sum operation circuit 56 outputs the operation result value by performing the sum operation processing to an output value of the determination circuit 15 obtained from the determination circuit 15 for each of the division values. The operation control circuit 57 controls the AD conversion REF cell REFC and the determination circuit 15 such that the determination circuit 15 performs the operation processing to each of the division values.

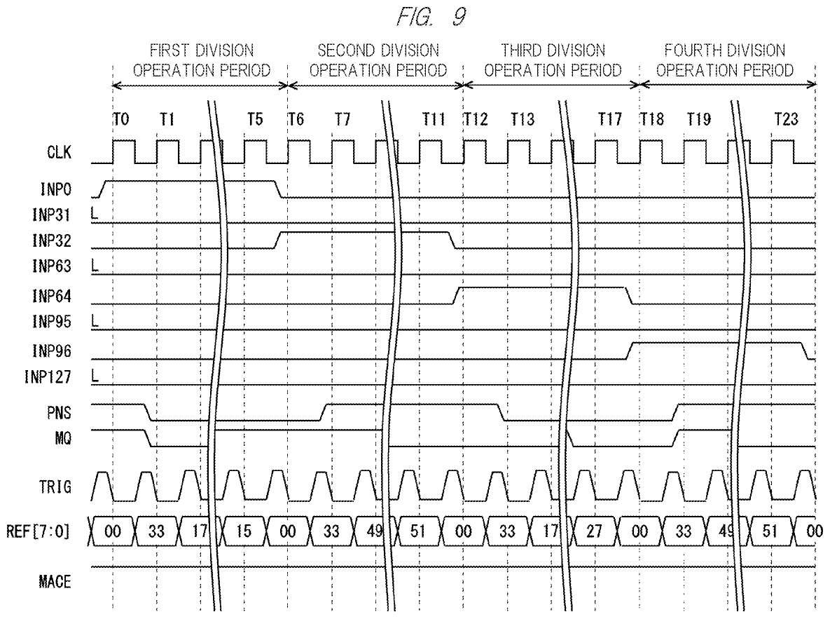

Then, operation of the semiconductor device 2 according to the second embodiment will be described. FIG. 9 is a timing chart for explaining the operation of the semiconductor device 2 according to the second embodiment. FIG. 9 also illustrates only a value of the highest-order bit and a value of the lowest-order bit of each of division values as an input value as similar to FIG. 6, and clear illustration of a signal related to other bits is omitted. Even in the second embodiment, the constant current source 14 also continues to operate during an operation period. Accordingly, a sum-product operation mode enable signal MACE is maintained at a high level.

As illustrated in FIG. 9, the semiconductor device 2 according to the second embodiment performs sequential operation processing to four division values, respectively, in four division operation periods. Specifically, FIG. 9 illustrates a first division operation period (an input period of an operation clock CLK at timings T0 to T5), a second division operation period (an input period of the operation clock CLK at timings T6 to T11), a third division operation period (an input period of the operation clock CLK at timings T12 to T17), and a fourth division operation period (an input period of the operation clock CLK at timings T18 to T23).

Specifically, in the first division operation period, operation processing is performed to the division value constituted by input values INP0 to INP31. In the second division operation period, operation processing is performed to the division value constituted by input values INP32 to INP63. In the third division operation period, operation processing is performed to the division value constituted by input values INP64 to INP95. In the fourth division operation period, operation processing is performed to the division value constituted by input values INP96 to INP127.

In the division operation period, the interference of the AD conversion REF cell REFC to the data lines PBL and NBL is stopped in response to the operation clock CLK to be input at a first timing in the division operation period, and the determination circuit 15 determines which of the data lines PBL and NBL is larger for each of the memory modules. By comparison at the first timing, the highest-order bit of an output value (e.g., an output value MQ) corresponding to each of the division values is determined. A logical value of the polarity control signal PNS at a second timing or later is determined in accordance with the determination result of the first timing.

At the second timing or later in each of the division operation periods, first to sixth bits of a reference control signal REF are sequentially turned on as a sequential analog/digital conversion sequence, to determine whether the bits remain to be turned on or off in accordance with the output value MQ. After each of the division operation periods ends, a sum of the respective output values MQ of the memory modules determined in each division operation period is calculated by the sum operation circuit 56, and a value obtained by the calculation is output as an operation result value.

From the foregoing description, the semiconductor device 2 according to the second embodiment connects all the memory units corresponding to one input value to the one set of data lines, gives division values to the memory units respectively in time division, and obtains an operation result value by calculating a sum of output values obtained in time division using the sum operation circuit 56.

As a result, in the semiconductor device 2 according to the second embodiment, it is only required to arrange the current source 12, the constant current source 14, the determination circuit 15, and the one set of data lines PBL and NBL, and therefore, a circuit scale can be made smaller than that of the first embodiment. In the semiconductor device 2 according to the second embodiment, an operation is performed for each of the memory units so that the number of memory cells to be collectively connected to the set of data lines is suppressed to a predetermined number or less, and therefore, the operation error can be suppressed as similar to the first embodiment.

### Third Embodiment

In a third embodiment, a semiconductor device 3 as a modification example of the semiconductor device 2 according to the second embodiment will be described. In the description of the third embodiment, the same components as the components described in the first and second embodiments are respectively denoted by the same reference numerals as those in the first and second embodiments, and description thereof is omitted.

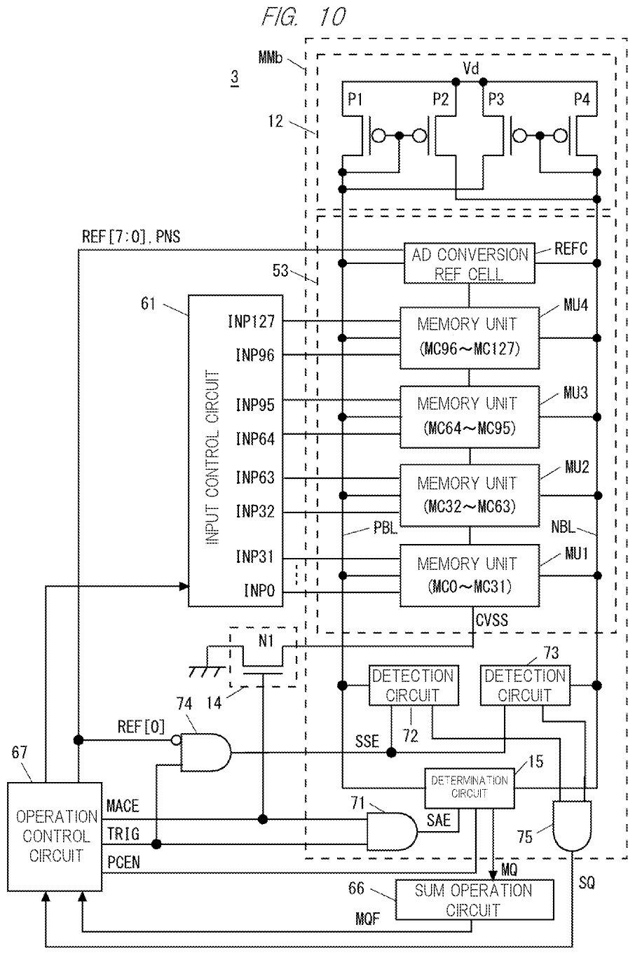

FIG. 10 is a block diagram of the semiconductor device 3 according to the third embodiment. Although a block illustrated in FIG. 10 is a block diagram focused on a current source 12, a cell array 53, a constant current source 14, a determination circuit 15, an input control circuit 61, a sum operation circuit 66, and an operation control circuit 67 in the semiconductor device 3, the semiconductor device 3 includes other circuit blocks such as a memory controller 10 as similar to the semiconductor device 1 according to the first embodiment.

As illustrated in FIG. 10, the semiconductor device 3 according to the third embodiment includes the input control circuit 61, the sum operation circuit 66, and the operation control circuit 67 instead of the input control circuit 51, the sum operation circuit 56, and the operation control circuit 57 in the semiconductor device 2. In the semiconductor device 3, AND gates 71, 74, and 75, a first detection circuit 72, and a second detection circuit 73 are added to the semiconductor device 2.

On the basis of an instruction from the operation control circuit 67, the input control circuit 61 performs switching between collective output of input values at one timing and division of each of input values into division values first and then output in time division. When the determination circuit 15 outputs the output value without no division operation, the sum operation circuit 66 outputs the finally determined output value as it is as the operation result value. When the determination circuit 15 outputs the output values in time division, the sum operation circuit 66 outputs a sum of the output values determined in time division as the operation result value. In the operation control circuit 67, a function of switching operation of the input control circuit 61 and the operation control circuit 67 in response to respective detection results by the first detection circuit 72 and the second detection circuit 7 described below is added to the operation control circuit 57.

On the basis of a voltage value of a first data line (e.g., a data line PBL), the first detection circuit 72 detects that the number of memory cells having a first value is a predetermined threshold value or more. On the basis of a voltage value of a second data line (e.g., a data line NBL), the second detection circuit 73 detects that the number of memory cells having a second value is a predetermined threshold value or more. In an example illustrated in FIG. 10, an output value of the first detection circuit 72 and an output value of the second detection circuit 73 are transmitted to the operation control circuit 67 after being synthesized by the AND gate 75. Specifically, in the semiconductor device 3, when both the first detection circuit 72 and the second detection circuit 73 detect that the number of memory cells connected to the data line is less than the threshold value, the AND gate 75 feeds a detection signal causing a high level to the operation control circuit 67. On the other hand, in the semiconductor device 3, when either one of the first detection circuit 72 and the second detection circuit 73 detects that the number of memory cells connected to the data line is the threshold value or more, the AND gate 75 feeds a detection signal causing a low level to the operation control circuit 67.

In the semiconductor device 3 according to the third embodiment, a logical sum of a trigger signal TRIG and an inverted value of a reference control signal REF[0] as the lowest-order bit of a reference control signal REF is calculated by the AND gate 74, and is fed as a second sense enable signal SSE to the first detection circuit 72 and the second detection circuit 73. As a result, the first detection circuit 72 and the second detection circuit 73 operate in a period during which a first operation clock in operation processing is input.

In the semiconductor device 3 according to the third embodiment, a logical sum of the trigger signal TRIG and a sum-product operation mode enable signal MACE is calculated by the AND gate 71, and is set as a first sense enable signal SAE. In the semiconductor device 3, the first sense enable signal SAE instead of the trigger signal TRIG is fed to the determination circuit 15. As a result, the determination circuit 15 can stop operating in a period during which the sum-product operation mode enable signal MACE is at a low level, regardless of a logical level of the trigger signal TRIG.

Operation of the semiconductor device 3 according to the third embodiment will be described. The operation of the semiconductor device 3 according to the third embodiment varies depending on respective detection results made by the first detection circuit 72 and the second detection circuit 73. In the following description, the operation in a case where both the first detection circuit 72 and the second detection circuit 73 detect that the number of memory cells connected to the data line is less than the threshold value will be described as first operation, and the operation in a case where either one of the first detection circuit 72 and the second detection circuit 73 detects that the number of memory cells connected to the data line is the threshold value or more will be described as second operation.

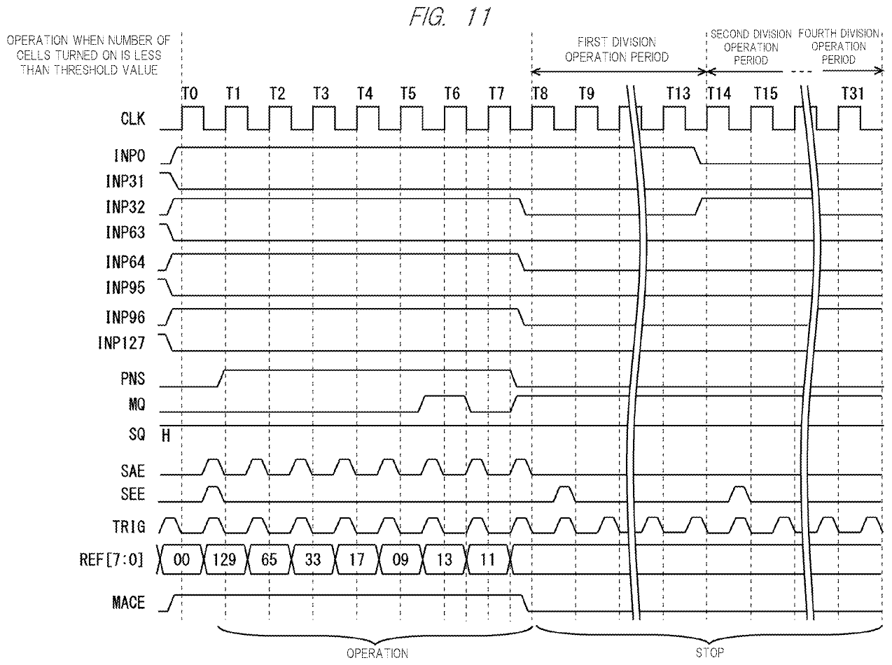

First, FIG. 11 is a timing chart for explaining the first operation of the semiconductor device 3 according to the third embodiment. FIG. 11 also illustrates only a value of the highest-order bit and a value of the lowest-order bit of each of division values as an input value as similar to FIG. 6, and clear illustration of a signal related to other bits is omitted.

As illustrated in FIG. 11, in the semiconductor device 3 according to the third embodiment, input values not divided are fed to all memory units in accordance with an operation clock CLK to be input at a first timing T0 of operation processing. In this period, a second sense enable signal SSE is brought into a high level, and the first detection circuit 72 and the second detection circuit 73 respectively determine the numbers of memory cells connected to the data lines PBL and NBL. In the first operation, the respective numbers of memory cells connected to the data lines PBL and NBL are less than the threshold value. Accordingly, in response to respective detection signals of the first detection circuit 72 and the second detection circuit 73, the operation control circuit 67 instructs the AD conversion REF cell REFC and the determination circuit 15 to perform operation in a state in which all the input values (e.g., INP0 to INP127) are fed to the memory cells. As a result, in the first operation, eight information processing cycles are performed to determine the operation result value in a period of timings T0 to T7.

In the first operation, at a timing T8 or later after the timing T7, the operation control circuit 67 brings a sum-product operation mode enable signal MACE into a low level, and therefore, a current to be fed to the memory cells and the AD conversion REF cell REFC is blocked, and the operation of the determination circuit 15 is stopped.

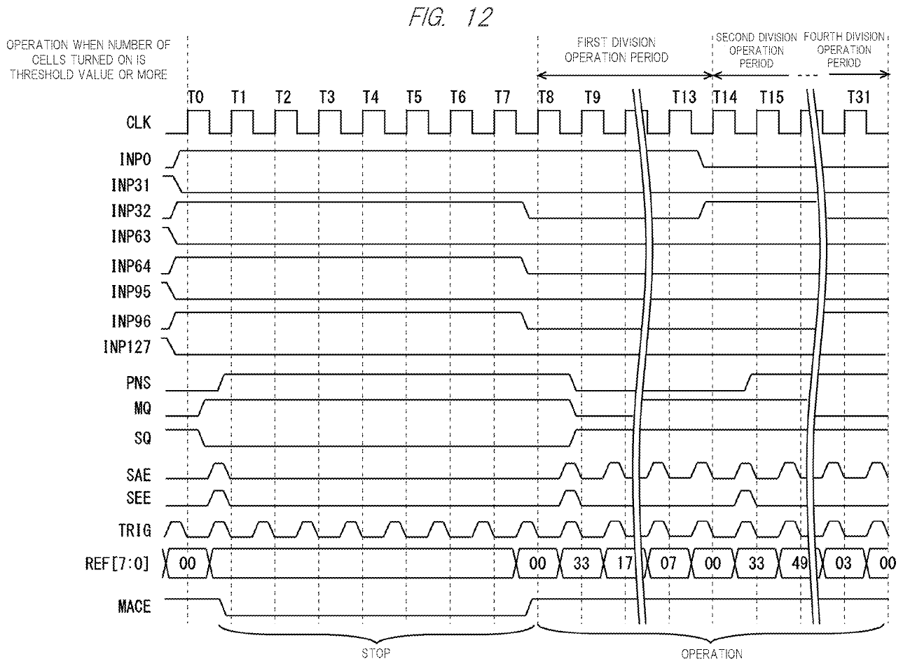

Then, FIG. 12 is a timing chart for explaining the second operation of the semiconductor device 3 according to the third embodiment. FIG. 12 also illustrates only a value of the highest-order bit and a value of the lowest-order bit of each of division values as an input value as similar to FIG. 6, and clear illustration of a signal related to other bits is omitted.

As illustrated in FIG. 12, in the semiconductor device 3 according to the third embodiment, input values not divided are fed to all memory units in accordance with an operation clock CLK to be input at a first timing T0 of operation processing. In this period, a second sense enable signal SSE is brought into a high level, and the first detection circuit 72 and the second detection circuit 73 respectively determine the numbers of memory cells connected to the data lines PBL and NBL. In the second operation, the number of memory cells connected to at least either one of the data lines PBL and NBL is the threshold value or more. Accordingly, in response to respective detection signals of the first detection circuit 72 and the second detection circuit 73, the operation control circuit 67 instructs the AD conversion REF cell REFC and the determination circuit 15 to perform operation corresponding to the division value at timing T8 or later. The input control circuit 61 outputs the input value as the division value in period of timings T8 to T31. Further, in the second operation, a sum-product operation mode enable signal MACE is brought into a low level in a period of the timings T1 to T7, and the sum-product operation mode enable signal MACE is brought into a high level at the timing T8 or later. As a result, in the second operation, in the period of the timings T0 to T7, a current to be fed to the memory cells and the AD conversion REF cell REFC is blocked, and operation of the determination circuit 15 is stopped. On the other hand, in the second operation, operation processing corresponding to the division values is performed at the timing T8 or later as similar to the operation described with reference to FIG. 9.

From the foregoing description, in the semiconductor device 3 according to the third embodiment, if the number of memory cells connected to the data line is less than the threshold value, the input values are collectively fed without being divided, to reduce the number of conversion processing cycles. As a result, in the semiconductor device 3 according to the third embodiment, power consumption can be more reduced than the semiconductor device 2 according to the second embodiment.

### Fourth Embodiment

In a fourth embodiment, a semiconductor device 4 including the semiconductor device 1 according to the first embodiment will be described. In the description of the fourth embodiment, the same components as the components described in the first embodiment are respectively denoted by the same reference numerals as those in the first embodiment, and description thereof is omitted.

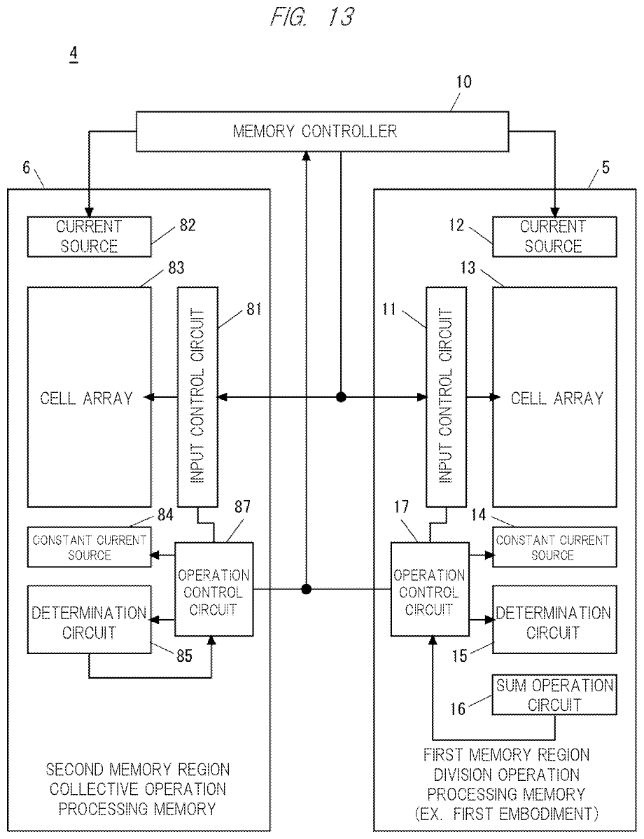

FIG. 13 is a block diagram of a semiconductor device 4 according to the fourth embodiment. As illustrated in FIG. 13, the semiconductor device 4 according to the fourth embodiment includes a first memory region 5 and a second memory region 6. The first memory region 5 includes the semiconductor device 1 described in the first embodiment. On the other hand, the second memory region 6 includes a collective operation processing memory having no function of performing operation corresponding to division values obtained by dividing an input value.

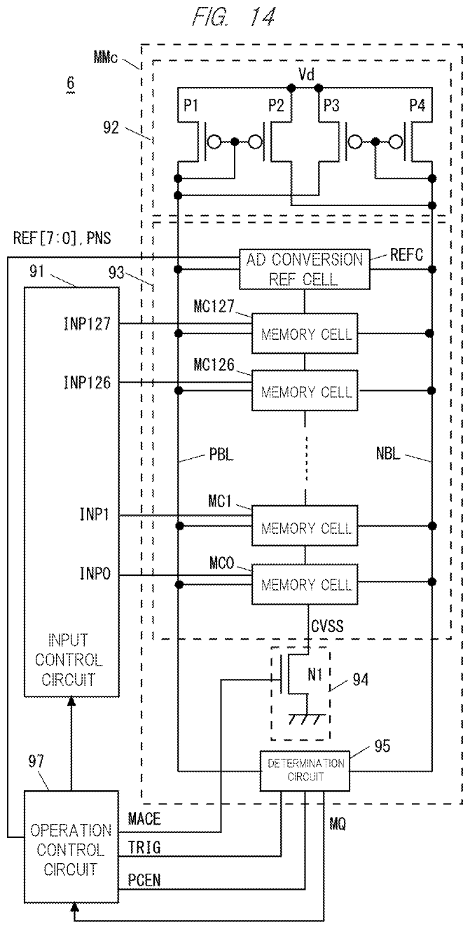

The collective operation processing memory includes an input control circuit 81, a current source 82, a cell array 83, a constant current source 84, a determination circuit 85, and an operation control circuit 87. For the second memory region 6, FIG. 14 illustrates a detailed block diagram of the collective operation processing memory arranged in the second memory region 6 in the semiconductor device 4 according to the fourth embodiment.

As illustrated in FIG. 14, in the collective operation processing memory, the input control circuit 91 has no function of generating division values, and collectively gives input values to memory cells. The current source 92, the constant current source 94, and the determination circuit 95 respectively have the same configurations as those of the current source 12, the constant current source 14, and the determination circuit 15. In the cell array 93, all memory cells are connected to one set of data lines as similar to the cell array 53, and there is no concept of a memory unit. The operation control circuit 97 is provided by adding only a function of performing operation at timings T0 to T7 illustrated in FIG. 11 to the operation control circuit 67.

When the first memory region 5 and the second memory region 6 are arranged as described above, a held value requiring a high operation accuracy can be held by the first memory region 5 while a held value not requiring a high operation accuracy can be held by the second memory region 6. Although the operation related to artificial intelligence frequently uses the sum-product operation made by the sum-product operation device mounted on each of the first memory region 5 and the second memory region 6, the high operation accuracy is not required for all operations. Accordingly, the memory region that holds the held value is separated depending on the operation accuracy to be required as described in the semiconductor device 4 according to the fourth embodiment, and therefore, both the operation speed and the operation accuracy can be achieved. Also, when the memory region is separated as described above, power consumption required for an operation can be reduced.

In the foregoing, the invention made by the inventors of the present application has been concretely described on the basis of the embodiments. However, it is needless to say that the present invention is not limited to the foregoing embodiments, and various modifications can be made within the scope of the present invention.

What is claimed is:

1. A semiconductor device comprising:
an input control circuit dividing a plurality of bit values representing an input value into a plurality of division values each having a predetermined number of bits and outputting the division values;
a plurality of memory units each including a plurality of memory cells each outputting a product of a held value represented by a ternary value and any one of the plurality of bit values representing the input value, each of the plurality of memory units corresponding to any one of the plurality of division values;
a first data line electrically connected with a memory cell outputting a first value among the memory cells;
a second data line electrically connected with a memory cell outputting a second value among the memory cells;
an information processing reference cell giving a reference value changing for each of information processing cycles to either one of the first data line and the second data line;
a determination circuit outputting, for each of the information processing cycles, a binary signal representing a value that differs depending on which of the number of the memory cells connected to the first data line and the number of the memory cells connected to the second data line is larger;
a sum operation circuit performing sum operation processing to an output value to be output for each of the division values by the determination circuit, and outputting a final operation result value; and
an operation control circuit controlling operation of the information processing reference cell and the determination circuit.

2. The semiconductor device according to claim 1,
wherein the first data line, the second data line, the information processing reference cell, and the determination circuit are provided for each of the memory units,
the input control circuit collectively gives the plurality of division values to the plurality of memory units,
the operation control circuit controls the information processing reference cell and the determination circuit such that the determination circuit performs operation processing in parallel within one period, and
the sum operation circuit outputs the operation result value by performing sum operation processing to an output value of the determination circuit obtained by the parallel processing.

3. The semiconductor device according to claim 1,
wherein the first data line, the second data line, the information processing reference cell, and the determination circuit are provided in common among the plurality of memory units,
the input control circuit gives the division values in time division to the plurality of memory units,
the operation control circuit controls the information processing reference cell and the determination circuit such that the determination circuit performs operation processing for each of the division values, and
the sum operation circuit outputs the operation result value by performing sum operation processing to an output value of the determination circuit obtained by the determination circuit for each of the division values.

4. The semiconductor device according to claim 1, further comprising:
a first detection circuit detecting that the number of memory cells each having the first value is a predetermined threshold value or more, on basis of a voltage value of the first data line; and
a second detection circuit detecting that the number of memory cells each having the second value is the predetermined threshold value or more, on basis of a voltage value of the second data line,
wherein the first data line, the second data line, the information processing reference cell and the determination circuit are provided in common among the plurality of memory units,
wherein both a period during which the input values are collectively given to the plurality of memory units and a period during which the division values are given in time division to the plurality of memory units,
wherein when at least one of the first detection circuit and the second detection circuit detects that the number of memory cells is the threshold value or more, the operation control circuit controls the information processing reference cell and the determination circuit such that the determination circuit performs operation processing in a period during which the division values are given in time division to the plurality of memory units, and the sum operation circuit outputs the operation result value by performing sum operation processing to the output value of the determination circuit obtained by the determination circuit for each of the division values, and
when both the first detection circuit and the second detection circuit detect that the number of memory cells is less than the threshold value, the operation control circuit controls the information processing reference cell and the determination circuit such that the determination circuit performs operation processing in a period during which the input values are collectively given to the plurality of memory units, and the sum operation circuit outputs the output value determined by the determination circuit as it is as the operation result value.

5. The semiconductor device according to claim 4,
wherein when a period during which one information processing result of a predetermined number of bits is determined by the output value of the determination circuit is set to one information processing period, the operation control circuit switches a period during which the determination circuit performs operation processing on basis of respective detection results of the first detection circuit and the second detection circuit to be output in a first information processing cycle of the one information processing period.

6. The semiconductor device according to claim 1, further comprising:
a first memory region and a second memory region,
wherein, as a first input control circuit, a first information processing reference cell, a first determination circuit and a first operation control circuit, the first memory region is provided with the first input control circuit, the plurality of memory units, the first data line, the second data line, the first information processing reference cell, the first determination circuit, the sum operation circuit and the first operation control circuit while using the input control circuit, the information processing reference cell, the determination circuit and the operation control circuit, respectively, and
the second memory region includes:
a second input control circuit collectively outputting a plurality of bit values representing the input value;
a plurality of memory cells outputting a product of the held value represented by a ternary value and any one of a plurality of bit values representing the input value;
a third data line electrically connected with a memory cell outputting a first value among the memory cells;
a fourth data line electrically connected with a memory cell outputting a second value among the memory cells;
a second information processing reference cell giving a reference value changing for each of information processing cycles to either one of the first data line and the second data line;
a second determination circuit outputting, for each of the information processing cycles, a binary signal representing a value that differs depending on which of the number of the memory cells connected to the first data line and the number of the memory cells connected to the second data line is larger; and
an operation control circuit controlling operation of the second determination circuit.
